(19) United States
(12) Patent Application Publication
(10) Pub. No.: US 2026/0107643 A1
(43) Pub. Date: Apr. 16, 2026

(54) DISPLAY PANEL, MANUFACTURING METHOD FOR DISPLAY PANEL, AND ELECTRONIC DEVICE

(71) Applicant: Hefei Visionox Technology Co., Ltd., Hefei (CN)

(72) Inventors: Wenyu ZENG, Hefei (CN); Shundong BAO, Hefei (CN); Zhiwei ZHOU, Hefei (CN)

(73) Assignee: Hefei Visionox Technology Co., Ltd., Hefei (CN)

(21) Appl. No.: 19/422,314

(22) Filed: Dec. 16, 2025

Related U.S. Application Data
(63) Continuation of application No. PCT/CN2025/102801, filed on Jun. 23, 2025.

(30) Foreign Application Priority Data
Jun. 24, 2024 (CN) 202410824746.8

(51) Int. Cl. H10K 59/122; H10K 59/12; H10K 59/80

(52) U.S. Cl. CPC H10K 59/122; H10K 59/1201; H10K 59/873

(57) ABSTRACT

Disclosed are a display panel and a manufacturing method therefor, and an electronic device. By forming isolation openings and light-transmitting openings separately at different etching processes, consistency of etching environment for a first display region and a second display region during the formation of a first isolation opening and a second isolation opening may be improved, ensuring that undercut lengths corresponding to the first isolation opening and the second isolation opening are the same, Thus, uniformity of lap joint effect between electrodes of light-emitting devices in the first display region and the second display region and an isolation structure may be improved, thereby improving uniformity of display effect in the first display region and the second display region.

### CROSS-REFERENCE TO RELATED APPLICATIONS

This application is a continuation of International Application No. PCT/CN2025/102801, filed on Jun. 23, 2025, which claims priority to Chinese Patent Application No. 202410824746.8, filed on Jun. 24, 2024. The disclosures of the aforementioned applications are hereby incorporated by reference in their entireties.

### FIELD

The present disclosure generally relates to the field of display technologies, and in particular, to a display panel and a manufacturing method therefor, and an electronic device.

### BACKGROUND

Organic Light Emitting Diodes (OLEDs) and flat-panel displays based on technologies such as Light Emitting Diodes (LEDs) and the like have become mainstream owing to advantages like high image quality, low power consumption, slim profile, and broad applicability, and are now widely used in mobile phones, televisions, notebook computers, desktop computers, and various other consumer electronic products.

In a traditional preparation process of OLED display panels, light-emitting pixels are typically patterned using a Fine Metal Mask (FMM). The FMM technology is mature and has rich experience in mass production. However, this technology also has problems such as limited precision and high cost. Technology of no fine metal mask eliminates limitations of traditional OLED processes on display screen size, resolution, and other screen performance, and has advantages of high performance, full-size scalability, and rapid turnaround. Patents of CN118251982A, CN115666161A, CN116648095A, CN117062489A, CN118678742A, CN118785761A, CN115224220A, CN118678729A, CN118660529A, and CN118660589A contain relevant content on the technology of no fine metal mask, for reference.

However, manufacturability of current OLED display products still needs to be improved.

### SUMMARY

To overcome shortcomings in the prior art mentioned above, the present disclosure aims to provide a display panel. The display panel is provided with a first display region and a second display region. The display panel includes: substrate; and an isolation structure, disposed on a side of the substrate and in the first display region and the second display region. The isolation structure includes a supporting portion and a shielding portion arranged on a side, facing away from the substrate, of the supporting portion. The isolation structure is provided with a plurality of isolation openings and at least one light-transmitting opening, and the plurality of isolation openings include a first isolation opening arranged in the first display region and a second isolation opening arranged in the second display region. The at least one light-transmitting opening is arranged in the second display region. At the first isolation opening and the second isolation opening, an orthogonal projection of a side, facing the shielding portion, of the supporting portion on the substrate is located within an orthogonal projection of a side, facing the supporting portion, of the shielding portion on the substrate. A distance between an orthogonal projection of the shielding portion, located in the first display region and at the first isolation opening, on the substrate and an orthogonal projection of the supporting portion, located in the first display region and at the first isolation opening, on the substrate is SA21; and a distance between an orthogonal projection of the shielding portion, located in the second display region and at the second isolation opening, on the substrate and an orthogonal projection of the supporting portion, located in the second display region and at the second isolation opening, on the substrate is SA22. A difference between SA21 and SA22 is less than 0.1 μm.

The present further provides a display panel provided with a first display region and a second display region. The display panel includes a substrate, and an isolation structure disposed on a side of the substrate, where the isolation structure includes a supporting portion and a shielding portion sequentially stacked in a direction away from the substrate, an orthogonal projection of a side, facing the shielding portion, of the supporting portion, on the substrate is located within an orthogonal projection of the shielding portion on the substrate, the isolation structure is provided with a plurality of isolation openings and at least one light-transmitting opening, the plurality of isolation openings include a plurality of first isolation openings and a plurality of second isolation openings, the plurality of first isolation openings are arranged in the first display region, and the plurality of second isolation openings and the at least one light-transmitting opening are arranged in the second display region; and a plurality of light-emitting devices, where the plurality of light-emitting devices include a plurality of first light-emitting devices and a plurality of second light-emitting devices emitting light of a first color, the plurality of first light-emitting devices are disposed in the first display region, the plurality of second light-emitting devices are disposed in the second display region, a portion of a first light-emitting device is located within a first isolation opening correspondingly, a portion of a second light-emitting device is located within a second isolation opening correspondingly; an orthogonal projection of a side, facing the substrate, of the supporting portion, on the substrate is a first orthogonal projection, an orthogonal projection of the shielding portion on the substrate is a second orthogonal projection; along a first direction, a distance between an edge of the first orthogonal projection and an edge of the second orthogonal projection at the first isolation opening corresponding to the first light-emitting device is SA21; a distance between an edge of the first orthogonal projection and an edge of the second orthogonal projection at the second isolation opening corresponding to the second light-emitting device is SA22, and SA21 is greater than SA22.

Another embodiment of the present disclosure is to provide a manufacturing method for a display panel. The method includes: providing a substrate; forming an isolation material layer on a side of the substrate, where the isolation material layer is located in the first display region and the second display region; etching the isolation material layer in a first etching step to form a plurality of isolation openings, where the plurality of isolation openings include a first isolation opening arranged in the first display region and a second isolation opening arranged in the second display region; and covering and protecting the plurality of isolation openings by other film layers in a second etching step and etching the isolation material layer to form at least one light-transmitting opening; or etching the isolation material layer in a first etching step to form at least one light-transmitting opening, where the at least one light-transmitting opening is arranged in the second display region; and covering and protecting the at least one light-transmitting opening by other film layers in a second etching step and etching the isolation material layer to form a plurality of isolation openings.

Another embodiment of the present disclosure is to provide an electronic device. The electronic device includes the display panel provided by the present disclosure, or the electronic device includes a display panel manufactured according to the manufacturing method for the display panel provided by the present disclosure.

### BRIEF DESCRIPTION OF THE DRAWINGS

FIG. 1 is a schematic diagram illustrating regions of a display panel.

FIG. 2 is a cross-sectional view illustrating a display panel in conventional technologies.

FIG. 3 is a schematic diagram of an isolation opening and a light-transmitting opening.

FIG. 4 is a cross-sectional view of a display panel according to an embodiment of the present disclosure.

FIG. 5 is a cross-sectional view of a display panel according to another embodiment of the present disclosure.

FIG. 6 is a cross-sectional view of a display panel according to still another embodiment of the present disclosure.

FIG. 7 is a cross-sectional view of a display panel according to yet still another embodiment of the present disclosure.

FIG. 8 is a schematic diagram of an isolation structure according to an embodiment.

FIG. 9 is a flowchart of a manufacturing method for a display panel according to an embodiment.

FIG. 10 is a schematic diagram of a manufacturing process of a display panel according to an embodiment of the present disclosure.

FIG. 11 is a schematic diagram of a manufacturing process of a display panel according to another embodiment of the present disclosure.

FIG. 12 is a schematic diagram of a manufacturing process of a display panel according to still another embodiment of the present disclosure.

FIG. 13 is a schematic diagram of a manufacturing process of a display panel according to yet still another embodiment of the present disclosure.

FIG. 14 is a schematic diagram of a manufacturing process of a display panel according to yet still another embodiment of the present disclosure.

FIG. 15 is a schematic diagram of a manufacturing process of a display panel according to yet still another embodiment of the present disclosure.

FIG. 16 is a schematic diagram of a manufacturing process of a display panel according to yet still another embodiment of the present disclosure.

FIG. 17 is a schematic diagram of a manufacturing process of a display panel according to yet still another embodiment of the present disclosure.

FIG. 18 is a schematic diagram of a manufacturing process of a display panel according to yet still another embodiment of the present disclosure.

FIG. 19 is a cross-sectional view of a display panel according to yet still another embodiment of the present disclosure.

FIG. 20 is a cross-sectional view of a display panel according to yet still another embodiment of the present disclosure.

FIG. 21 is a cross-sectional view of a display panel according to yet still another embodiment of the present disclosure.

FIG. 22 is a cross-sectional view of a display panel according to yet still another embodiment of the present disclosure.

FIG. 23 is a cross-sectional view of a display panel according to yet still another embodiment of the present disclosure.

FIG. 24 is a cross-sectional view of a display panel according to yet still another embodiment of the present disclosure.

### DETAILED DESCRIPTION OF THE EMBODIMENTS

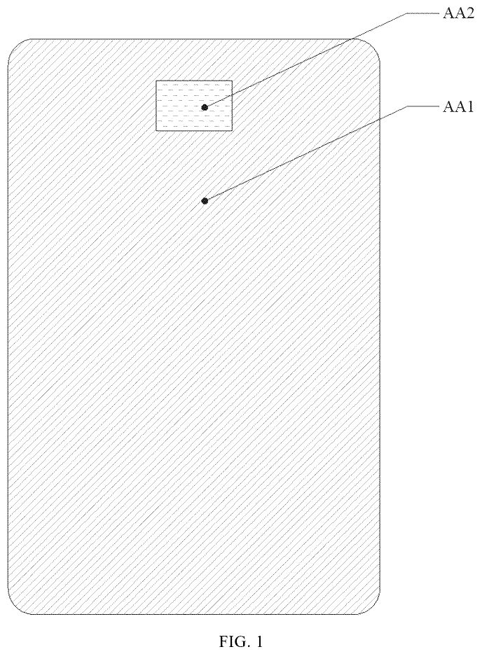

In some electronic devices, referring to FIG. 1, the display panel is provided with a first display region AA1 and a second display region AA2 to install optical components (such as cameras, light sensors, etc.) beneath a display panel while ensuring full-screen display of the display panel. The first display region AA1 is a normal display region, and the second display region AA2 is a light-transmitting display region. Compared with the normal display region, a light-transmitting opening needs to be arranged in the light-transmitting display region of the display panel to allow external light to transmit through the display panel and reach a region under the display panel.

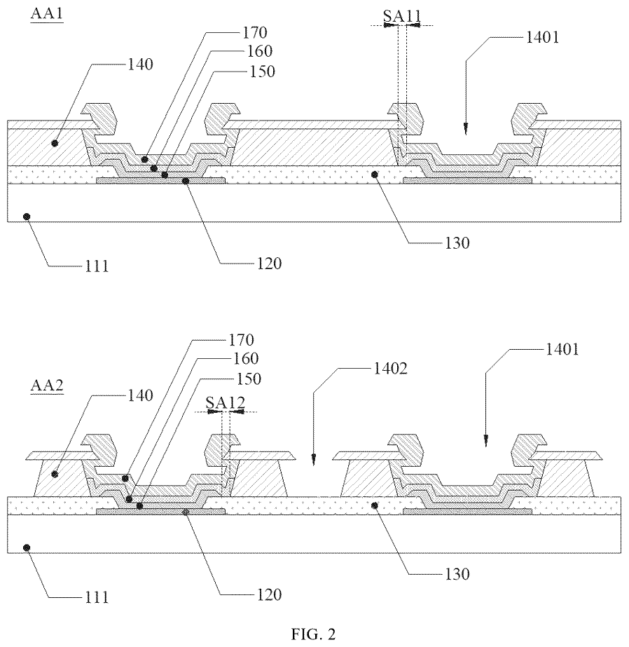

In some display panels, referring to FIG. 2, an isolation structure 140 is provided to disconnect an organic film layer of adjacent sub-pixels during an evaporation process. For example, such a display panel includes a substrate 111, an isolation structure 140 provided with an isolation opening and located on a side of the substrate 111, and a light-emitting device at least partially located within the isolation opening. The light-emitting device includes a first electrode 120, a light-emitting unit 150 and a second electrode 160. In this case, compared with a normal display region where the isolation structure 140 only needs to be provided with a first isolation opening 1401 for accommodating the light-emitting device, in the light-transmitting display region, the isolation structure 140 needs to be further provided with a light-transmitting opening 1402 besides a second isolation opening 1403. In an existing scheme, the light-transmitting opening 1402, the first isolation opening 1401 and the second isolation opening 1403 are formed in a same etching process.

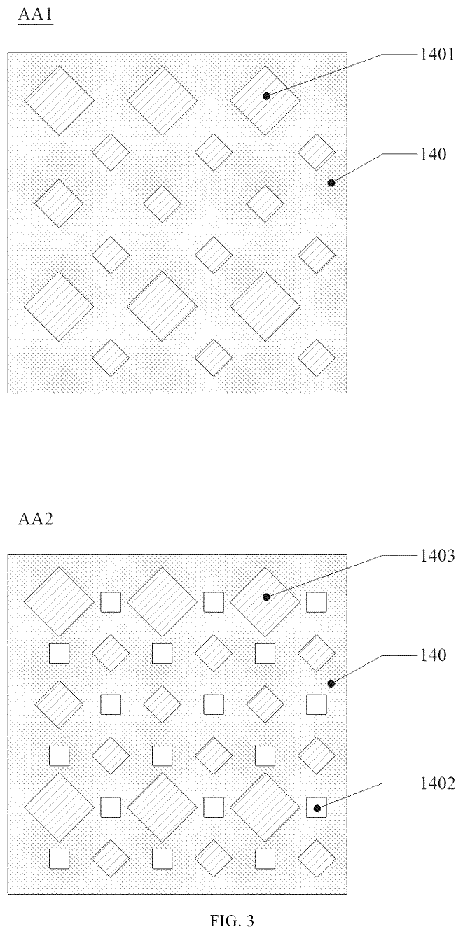

Referring to FIGS. 2 to 3, inventors have found that in such display panels shown in FIGS. 2 to 3, since additional light-transmitting openings need to be arranged in the light-transmitting display region, a density of openings in the light-transmitting display region is greater than that in the normal display region. Therefore, when the first isolation opening 1401, the light-transmitting opening 1402 and the second isolation opening 1403 are formed through wet etching, the normal display region and the light-transmitting display region are etched in different environment during the etching process, of which consumption rates of wet etching solution are also different. As a result, an undercut length SA11, formed by wet etching on the isolation structure 140 corresponding to the first isolation opening 1401 in the normal display region, differs from an undercut length SA12, formed by wet etching on the isolation structure 140 corresponding to the second isolation opening 1403 in the light-transmitting display region. For example, the undercut length SA11 of the isolation structure 140 corresponding to the first isolation opening 1401 in the normal display region is greater than the undercut length SA12 of the isolation structure 140 corresponding to the second isolation opening 1403 in the light-transmitting display region. Consequently, a lap joint effect between a second electrode 160 subsequently formed and the isolation structure 140 varies, impairing display uniformity between the normal display region and the light-transmitting display region. In the present disclosure, the term “density” refers to a ratio, per unit area, of an area of orthogonal projections of openings on the substrate to an area of an orthogonal projection of the normal display region or the light-transmitting display region on the substrate.

In view of above, embodiments of the present disclosure provide a solution capable of improving consistency of undercut lengths corresponding to isolation openings at different positions of the display panel. The solution offered by the embodiments will be described in detail below.

Referring to FIG. 1, FIG. 1 is a schematic diagram of a display panel according to the embodiment. The display panel includes a first display region AA1 and a second display region AA2. In one embodiment, the first display region AA1 at least partially surrounds the second display region AA2.

In this embodiment, both the first display region AA1 and the second display region AA2 have display functions. The second display region AA2 is also light-transmitting, allowing external light to transmit through the display panel from one side to the other via the second display region AA2.

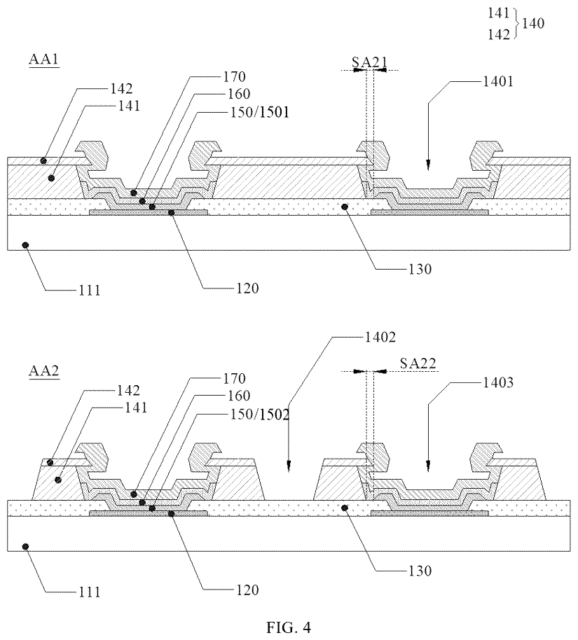

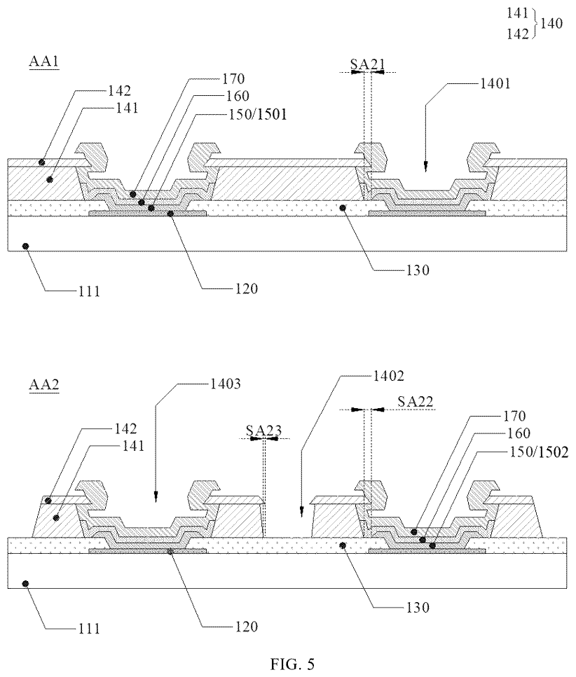

In one embodiment, referring to FIGS. 4 to 5, the display panel provided by this embodiment may include a substrate 111 and an isolation structure 140 located on a side of the substrate 111.

The substrate 111 may be made of a flexible material, such as Polyimide (Pi). The substrate 111 may also be made of a rigid material, such as glass.

The isolation structure 140 is disposed in the first display region AA1 and the second display region AA2. The isolation structure 140 is provided with a plurality of isolation openings and at least one light-transmitting opening 1402. Referring to FIG. 3, the plurality of isolation openings include a first isolation opening 1401 arranged in the first display region AA1 and a second isolation opening 1403 arranged in the second display region AA2, and the at least one light-transmitting opening 1402 is arranged in the second display region AA2.

In this embodiment, the isolation structure 140 in the first display region AA1 has a first undercut length SA21 at the first isolation opening 1401, the isolation structure 140 in the second display region AA2 has a second undercut length SA22 at the second isolation opening 1403. A difference between the first undercut length SA21 and the second undercut length SA22 is less than 0.1 μm. For example, in some embodiments, the first undercut length SA21 may be equal to the second undercut length SA22. For example, in some embodiments, the first undercut length SA21 may also be greater than the second undercut length SA22.

Thus, when the first display region AA1 is only provided with the first isolation opening 1401 and the second display region AA2 is provided with the second isolation opening 1403 and the light-transmitting opening 1402, consistency between the first undercut length SA21 corresponding to the first isolation opening 1401 and the second undercut length SA22 corresponding to the second isolation opening 1403 may be improved, and uniformity of lap joint effect between an electrode of a light-emitting device and the isolation structure in the first display region AA1 and the second display region AA2 may be improved, thereby improving uniformity of display effect of the two regions.

In this embodiment, the first isolation opening 1401 and the second isolation opening 1403 may be formed in a same etching process, while the light-transmitting opening 1402 may be formed in a different etching process. For example, when the light-transmitting opening 1402 is etched, the first isolation opening 1401 and the second isolation opening 1403 are covered and protected by other film layers. In one embodiment, when the first isolation opening 1401 and the second isolation opening 1403 are etched, the light-transmitting opening 1402 is covered and protected by other film layers.

Based on the above design, when the first isolation opening 1401 and the second isolation opening 1403 are etched, a density of openings that need to be etched in the first display region AA1 is the same as that in the second display region AA2. Thus, it ensures consistency of etching environment for the first display region AA1 and the second display region AA2 during the etching process, and the undercut lengths corresponding to the first isolation opening 1401 and the second isolation opening 1403 are equal or similar, thereby improving the uniformity of lap joint effect between the electrode of the light-emitting device and the isolation structure 140 in the first display region AA1 and the second display region AA2, and further improving the uniformity of display effect of these two regions.

In some embodiments, referring to FIG. 4, the isolation structure 140 includes a supporting portion 141 and a shielding portion 142 disposed on a side, facing away from the substrate 111, of the supporting portion 141.

At the first isolation opening 1401 and the second isolation opening 1403, an orthogonal projection of a side, facing the shielding portion 142, of the supporting portion 141, on the substrate 111 is located within an orthogonal projection of a side, facing the supporting portion 141, of the shielding portion 142, on the substrate 111. For example, on a side, facing the first isolation opening 1401 or the second isolation opening 1403, of the isolation structure 140, the supporting portion 141 is set back from the shielding portion 142, to form an undercut structure.

In this embodiment, during formation of the first isolation opening 1401 and the second isolation opening 1403, dry etching may be first used to perform patterned etching on the shielding portion 142 and at least part of the supporting portion 141, and then wet etching may be used to etch a sidewall of the supporting portion 141.

In this case, a distance between an orthogonal projection of a side, close to the first isolation opening 1401, of the shielding portion 142 arranged in the first display region AA1, on the substrate 111 and an orthogonal projection of a side, close to the first isolation opening 1401, of the supporting portion 141 arranged in the first display region AA1, on the substrate 111 is a first undercut length SA21.

That is, at the first isolation opening 1401, the first undercut length SA21 is a distance between an end, close to the first isolation opening 1401, of the orthogonal projection of the shielding portion 142 on the substrate 111 and an end, close to the first isolation opening 1401, of the orthogonal projection of the supporting portion 141 on the substrate 111.

A distance between an orthogonal projection of a side, close to the second isolation opening 1403, of the shielding portion 142 arranged in the second display region AA2, on the substrate 111 and an orthogonal projection of a side, close to the second isolation opening 1403, of the supporting portion 141 arranged in the second display region AA2, on the substrate 111 is a second undercut length SA22.

That is, at the second isolation opening 1403, the second undercut length SA22 is a distance between an end, close to the second isolation opening 1403, of the orthogonal projection of the shielding portion 142 on the substrate 111 and an end, close to the second isolation opening 1403, of the orthogonal projection of the supporting portion 141 on the substrate 111.

In some embodiments, referring to FIG. 4 again, a side, close to a light-transmitting opening 1402, of the shielding portion 142 located in the second display region AA2 is flush with a side, close to the light-transmitting opening 1402, of the supporting portion 141 located in the second display region AA2. In the present disclosure, when it is mentioned that the structure is “flush with” one another, it means that sides of a plurality of structures are located on a same straight line in a longitudinal section.

For example, the light-transmitting opening 1402 may be obtained through dry etching.

In some embodiments, referring to FIG. 5, at the light-transmitting opening 1402, an orthogonal projection of a side, facing the shielding portion 142, of the supporting portion 141 located in the second display region AA2 is located within an orthogonal projection of the shielding portion 142 located in the second display region AA2 on the substrate 111. That is, at the light-transmitting opening 1402, the supporting portion 141 is set back from the shielding portion 142, to form an undercut structure.

In this embodiment, the undercut lengths of the second isolation opening 1403 and the light-transmitting opening 1402 may be different.

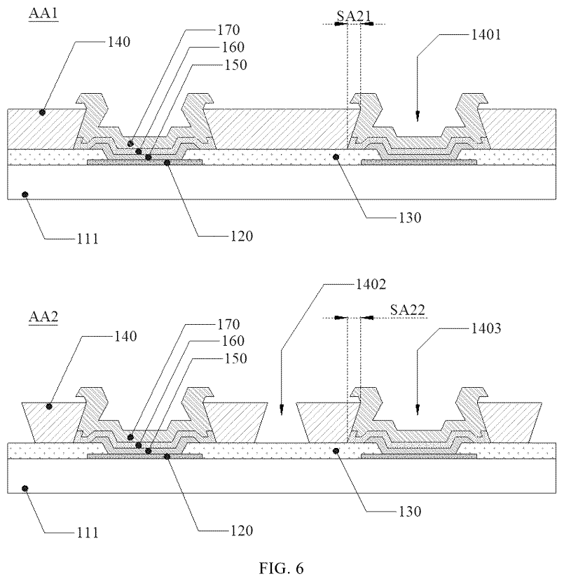

In some embodiments, referring to FIG. 6, the isolation structure 140 is an integrated structure, having a first surface facing a substrate 111 and a second surface facing away from the substrate 111. An orthogonal projection of the first surface on the substrate 111 is located within an orthogonal projection of the second surface on the substrate 111. For example, a cross-sectional shape of the isolation structure is an inverted trapezoid.

In this case, a distance between an end, close to the first isolation opening 1401, of an orthogonal projection of the second surface in the first display region AA1 on the substrate 111 and an end, close to the first isolation opening 1401, of an orthogonal projection of the first surface in the first display region AA1 on the substrate 111 is a first undercut length SA21.

That is, at the first isolation opening 1401, the first undercut length SA21 is a distance between an end, close to the first isolation opening 1401, of the orthogonal projection of the second surface on the substrate 111 and an end, close to the first isolation opening 1401, of the orthogonal projection of the first surface on the substrate 111.

A distance between an end, close to the second isolation opening 1403, of an orthogonal projection of the second surface in the second display region AA2 on the substrate 111 and an end, close to the second isolation opening 1403, of an orthogonal projection of the first surface in the second display region AA2 on the substrate 111 is a second undercut length SA22.

That is, at the second isolation opening 1403, the second undercut length SA22 is a distance between an end, close to the second isolation opening 1403, of the orthogonal projection of the second surface on the substrate 111 and an end, close to the second isolation opening 1403, of the orthogonal projection of the first surface on the substrate 111.

In some embodiments, referring to FIG. 3, the light-transmitting opening 1402 is located between adjacent second isolation openings 1403.

In one embodiment, a density of the first isolation opening 1401 located in the first display region AA1 is the same as a density of the second isolation opening 1403 located in the second display region AA2. Thus, when the first isolation opening 1401 and the second isolation opening 1403 are etched, etching environments for the first isolation opening 1401 and the second isolation opening 1403 are the same, and consistency of the undercut lengths corresponding to the isolation openings in the first display region AA1 and the second display region AA2 may be improved.

In some embodiments, referring to FIGS. 4 to 5 again, the display panel may further include light-emitting devices at least partially located within the first isolation opening 1401 and the second isolation opening 1403. The light-emitting device includes a first electrode 120, a light-emitting unit 150 and a second electrode 160 successively stacked in a direction facing away from the substrate 111. For example, in this embodiment, the light-emitting device is only arranged within the first isolation opening 1401 and the second isolation opening 1403, but not within the light-transmitting opening 1402.

In some embodiments, referring to FIGS. 4 to 5 again, the display panel may further include a plurality of light-emitting devices 150. The plurality of light-emitting devices 150 include a plurality of first light-emitting devices 1501 and a plurality of second light-emitting devices 1502 emitting light of a first color. The plurality of first light-emitting devices 1501 are located in the first display region AA1, and the plurality of second light-emitting devices 1502 are located in the second display region AA2. A first light-emitting device 1501 is partially located within a corresponding first isolation opening 1401, and a second light-emitting device 1502 is partially located within a corresponding second isolation opening 1403.

Therein, an orthogonal projection of a side, facing the substrate 111, of the supporting portion 141, on the substrate 111 is a first orthogonal projection, and an orthogonal projection of the shielding portion 142 on the substrate 111 is a second orthogonal projection. Along a first direction, at a first isolation opening 1401 corresponding to the first light-emitting device 1501, a distance between an edge of the first orthogonal projection and an edge of the second orthogonal projection is a first undercut length SA21. At a second isolation opening 1403 corresponding to the second light-emitting device 1502, a distance between an edge of the first orthogonal projection and an edge of the second orthogonal projection is a second undercut length SA22. For example, in some embodiments, SA21 is greater than SA22. The first direction is parallel to the substrate 111 on the cross-section shown in FIG. 4 or FIG. 5.

In some embodiments, referring to FIG. 5 again, along the first direction, at the light-transmitting opening 1402, a distance between an edge of the first orthogonal projection and an edge of the second orthogonal projection is a third undercut length SA0. For example, in some embodiments, SA0 is greater than SA21.

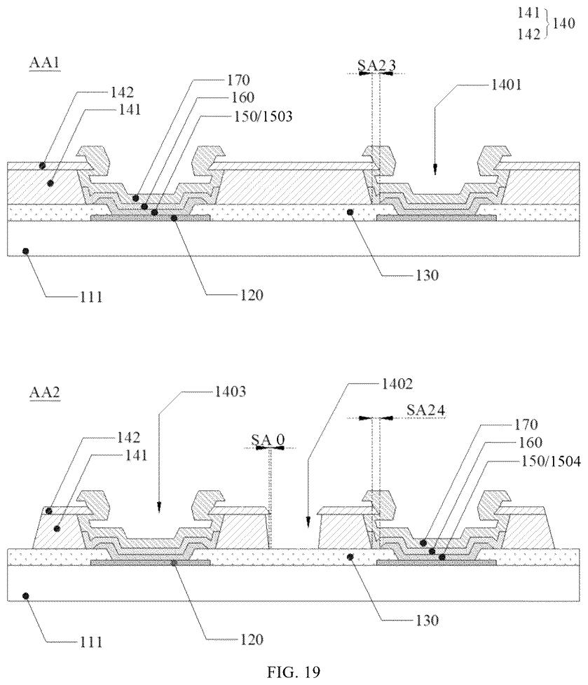

In some embodiments, referring to FIG. 19, the display panel may further include a plurality of light-emitting devices 150, and the plurality of light-emitting devices 150 may include a plurality of third light-emitting devices 1503 and a plurality of fourth light-emitting devices 1504 emitting light pf a second color. The second color light is different from the first color light.

Therein the plurality of third light-emitting devices 1503 are located in the first display region AA1. A third light-emitting device 1503 is partially located within a corresponding first isolation opening 1401. At a first isolation opening 1401 corresponding to the third light-emitting device 1503, a distance between an edge of the first orthogonal projection and an edge of the second orthogonal projection is a fourth undercut length SA23. The plurality of fourth light-emitting devices 1504 are located in the second display region AA2. A fourth light-emitting device 1504 is partially located within a corresponding second isolation opening 1403. At a second isolation opening 1403 corresponding to the fourth light-emitting device 1504, a distance between an edge of the first orthogonal projection and an edge of the second orthogonal projection is a fifth undercut length SA24.

In some embodiments, SA23 is greater than SA24, SA21 is greater than SA23, and SA22 is greater than SA24. A difference between SA0 and SA21 is less than a difference between SA0 and SA23, and a difference between SA0 and SA22 is less than a difference between SA0 and SA24.

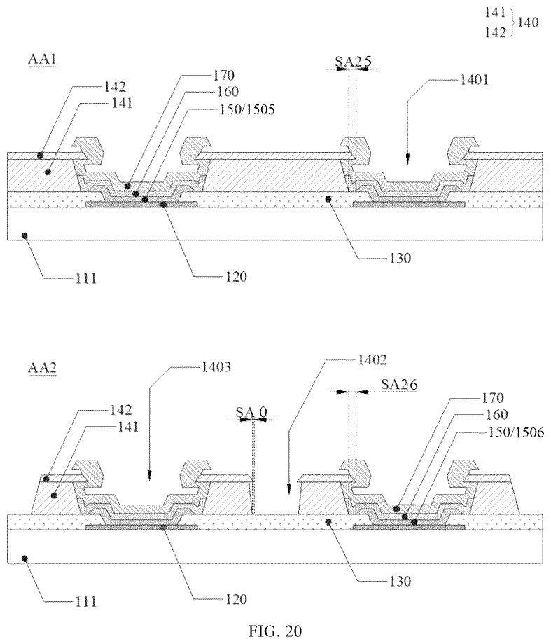

In some embodiments, referring to FIG. 20, the display panel may further include a plurality of light-emitting devices 150, and the plurality of light-emitting devices 150 may include a plurality of fifth light-emitting devices 1505 and a plurality of sixth light-emitting devices 1506 emitting light of a third color. The first color light, the second color light and the third color light are different from each other.

Therein, the plurality of fifth light-emitting devices 1505 are located in the first display region AA1. A fifth light-emitting device 1505 is partially located within a corresponding first isolation opening 1401. At a first isolation opening 1401 corresponding to the fifth light-emitting device 1505, a distance between an edge of the first orthogonal projection and an edge of the second orthogonal projection is a sixth undercut length SA25. The plurality of sixth light-emitting devices 1506 are located in the second display region AA2. A sixth light-emitting device 1506 is partially located within the corresponding second isolation opening 1403. At a second isolation opening 1403 corresponding to the sixth light-emitting device 1506, a distance between an edge of the first orthogonal projection and an edge of the second orthogonal projection is a seventh undercut length SA26.

In the manufacturing method for the display panel corresponding to the above embodiment, during an etching process performed on an isolation material layer, the plurality of isolation openings and the at least one light-transmitting opening are etched in a single etching process. Therefore, during a manufacturing process of the plurality of light-emitting devices of different colors, since the light-transmitting opening is partially consumed in an evaporation process corresponding to each color, correspondingly, the undercut length SA0 of the light-transmitting opening is greater than the undercut length of the isolation opening.

For example, in some embodiments, SA25 is greater than SA26, SA23 is greater than SA25, and SA24 is greater than SA26. A difference between SA0 and SA23 is less than a difference between SA0 and SA25, and a difference between SA0 and SA24 is less than a difference between SA0 and SA26.

In some embodiments, the first colored light is red, the second colored light is green, and the third colored light is blue. In some embodiments, SA0>SA21>SA22>SA23>SA24>SA25>SA26.

In some embodiments, a difference between SA21 and SA22 is less than or equal to 0.4 μm.

In some embodiments, a difference between SA0 and SA21 ranges from 0.1 μm to 0.4 μm.

In one embodiment, a difference between SA21 and SA22 is less than or equal to 0.2 μm.

In one embodiment, a difference between SA0 and SA21 ranges from 0.1 μm to 0.2 μm.

The isolation structure 140 is conductive, and the second electrode 160 extends to be electrically connected to the isolation structure 140.

In one embodiment, an orthogonal projection of the light-transmitting opening 1402 on the substrate 111 and an orthogonal projection of the first electrode 120 on the substrate 111 do not completely coincide. Thus, light transmittance of the second display region AA2 may be improved.

In some embodiments, the display panel may further include a pixel defining layer 130 located between the isolation structure 140 and the substrate 111. The pixel defining layer 130 is provided with a plurality of pixel openings. An orthogonal projection of a pixel opening on the substrate 111 is located within an orthogonal projection of the first isolation opening 1401 and the second isolation opening 1403 on the substrate 111. That is, in this embodiment, the pixel opening communicates with the isolation opening, jointly forming a cavity for accommodating the light-emitting device.

In some embodiments, the pixel defining layer 130 includes a light-transmitting region. An orthogonal projection of the light-transmitting region on the substrate 111 at least partially overlaps with the orthogonal projection of the light-transmitting opening 1402 on the substrate 111. A material of the pixel defining layer 130 in the light-transmitting region includes a light-transmitting material. Thus, light transmittance of the second display region AA2 may be improved.

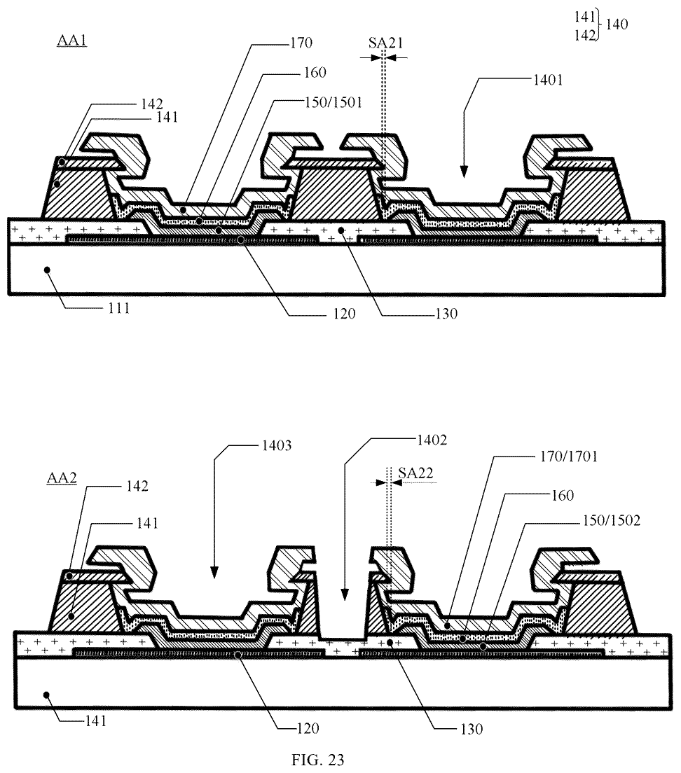

In some embodiments, referring to FIG. 23, the pixel defining layer 130 is disposed in the first display region AA1 and the second display region AA2. At a same light-transmitting opening 1402, a side, close to the supporting portion 141, of the pixel defining layer 130, a side of the shielding portion 142, a side of the supporting portion 141, and a side of a first encapsulation unit 1701 are flush with each other.

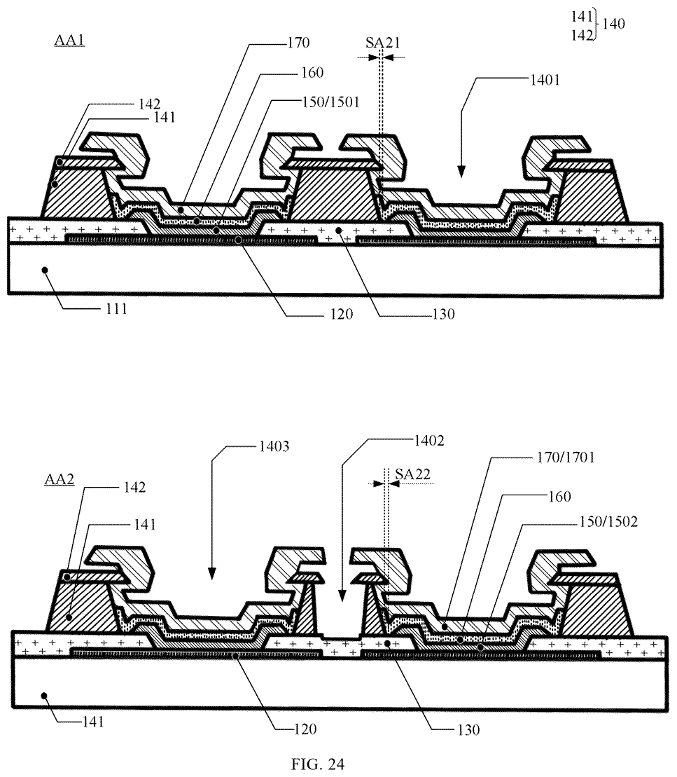

In some embodiments, referring to FIG. 24, the pixel defining layer 130 is disposed in the first display region AA1 and the second display region AA2. At a same light-transmitting opening 1402, a side, close to the supporting portion 141, of the pixel defining layer 130, is not coplanar with a side, facing the light-transmitting opening 1402, of the supporting portion 141.

In some embodiments, the display panel may further include an encapsulation unit 170 located on the side, facing away from the substrate 111, of the second electrode 160. At least part of the encapsulation unit is located within the isolation opening, and extends from the isolation openings to a side, facing away from the substrate 111, of the isolation structure 140.

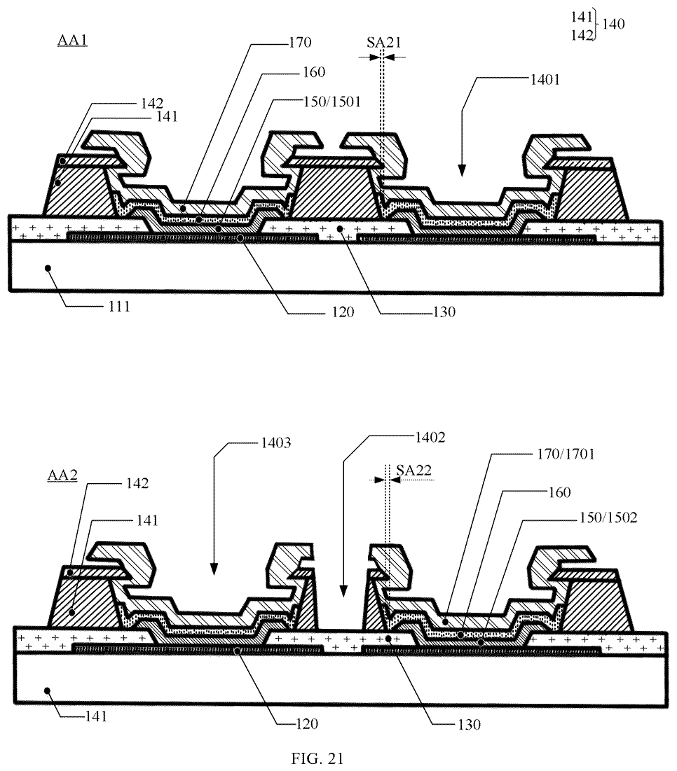

In some embodiments, referring to FIG. 21, the display panel may further include a plurality of encapsulation units. At least part of an encapsulation unit is located within a corresponding isolation opening, and extends from the isolation opening to a side, facing away from the substrate 111, of the isolation structure. The plurality of encapsulation units include a plurality of first encapsulation units 1701. A first encapsulation unit 1701 is located on a side, facing away from the substrate 111, of a corresponding second light-emitting device 1502. An orthogonal projection of the first encapsulation unit 1701, located on a side, facing away from the substrate 111, of the isolation structure, on the substrate 111 is located within the second orthogonal projection.

In some embodiments, referring to FIG. 21, at a same light-transmitting opening, a side of the shielding portion, a side of the supporting portion and a side of the first encapsulation unit are flush with each other.

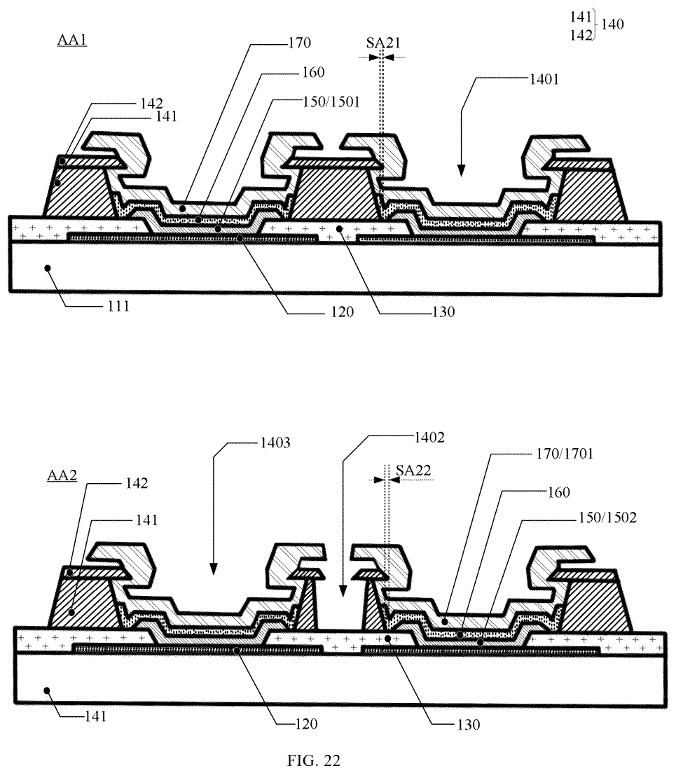

In some embodiments, referring to FIG. 22, at a same light-transmitting opening, a side of the shielding portion 142 is flush with a side of the first encapsulation unit 1701, and an orthogonal projection of a side, facing the shielding portion 142, of the supporting portion 141 on the substrate 111 is located within an orthogonal projection of the shielding portion 142 on the substrate 111.

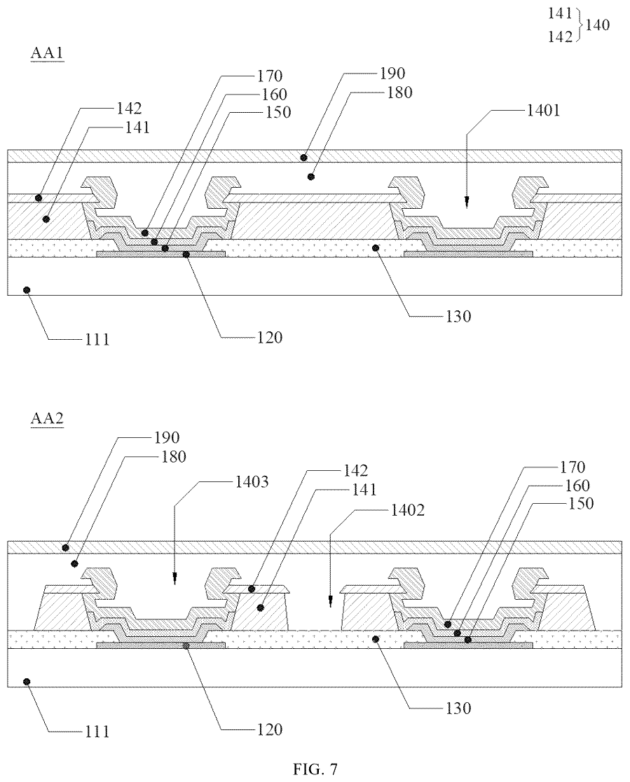

In one embodiment, referring to FIG. 7, the display panel may further include a second encapsulation layer 180 and a third encapsulation layer 190 located on a side, facing away from the substrate 111, of the encapsulation unit 170. The second encapsulation layer 180 is located on a side, facing away from the substrate 111, of the encapsulation unit 170, and the first isolation opening 1401 and the second isolation opening 1403 are filled with the second encapsulation layer 180.

In one embodiment, a material of the encapsulation unit 170 and the third encapsulation layer 190 may include an inorganic material, while a material of the second encapsulation layer 180 may include an organic material. For example, the encapsulation unit 170 and the third encapsulation layer 190 may be formed by Chemical Vapor Deposition (CVD), and the second encapsulation layer 180 may be formed by Ink-jet Printing (IJP).

In one embodiment, the light-transmitting opening 1402 is filled with the second encapsulation layer 180.

In some embodiments, etching resistance of the supporting portion 141 is less than etching resistance of the shielding portion 142.

In one embodiment, a material of the supporting portion 141 includes Aluminium (Al), and/or a material of the shielding portion 142 includes Titanium (Ti).

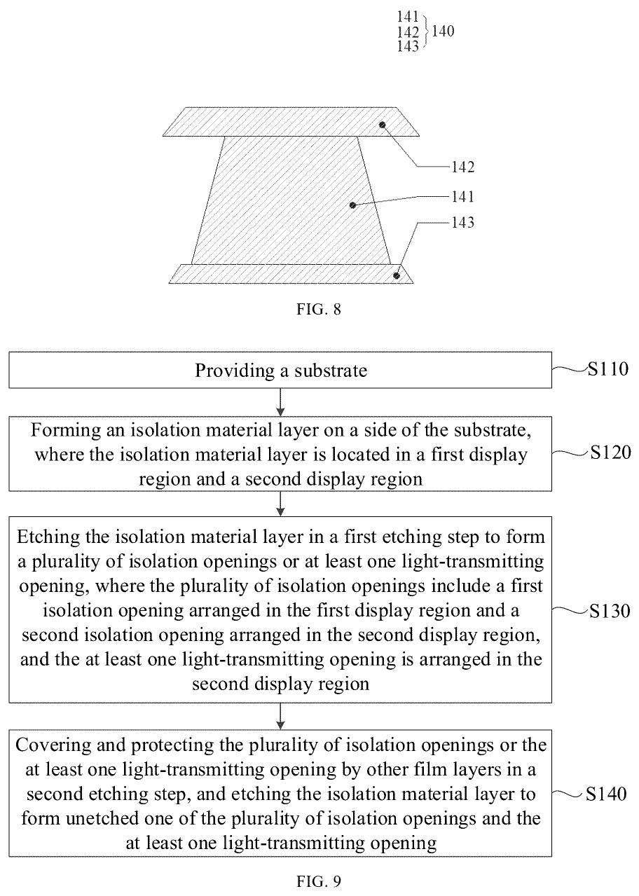

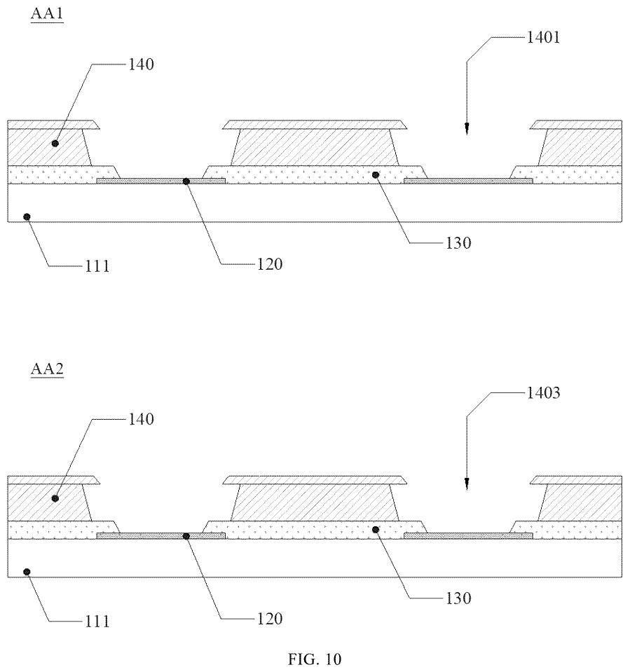

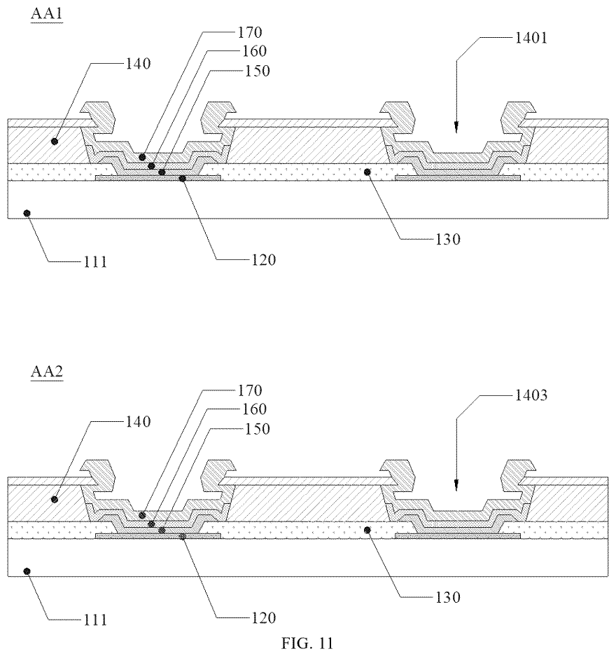

In one embodiment, referring to FIG. 8, the isolation structure may further include a transition portion 143 located between the supporting portion 141 and the substrate 111. In some embodiments, an orthogonal projection of a side, facing the transition portion 143, of the supporting portion 141, on the substrate 111 is located within an orthogonal projection of the transition portion 143 on the substrate 111. At an isolation opening, the orthogonal projection of the transition portion 143 on the substrate 111 is located within an orthogonal projection of the shielding portion 142 on the substrate 111.

In one embodiment, a material of the transition portion 143 may include at least one of Molybdenum (Mo) and Ti.

In one embodiment, a material of the supporting portion 141 may include Al.

In one embodiment, a material of the shielding portion 142 may include Ti.

In one embodiment, the shielding portion 142 may be of a double-layer structure. A material of a side, facing away from the supporting portion 141, of the shielding portion 143 may include Indium Tin Oxide (ITO), and a material of a side, facing the supporting portion 141, of the shielding portion 143 may include Ti.

The present disclosure further provides a manufacturing method for a display panel. Referring to FIG. 9, the display panel is provided with a first display region AA1 and a second display region AA2. The method may include the following steps.
Step S110: providing a substrate.
Step S120: forming an isolation material layer on a side of the substrate, where the isolation material layer is located in a first display region and a second display region.
Step S130: etching the isolation material layer in a first etching step to form a plurality of isolation openings or at least one light-transmitting opening, where the plurality of isolation openings include a first isolation opening arranged in the first display region and a second isolation opening arranged in the second display region and the at least one light-transmitting opening is arranged in the second display region.
Step S140: covering and protecting the plurality of isolation openings or the at least one light-transmitting opening by other film layers in a second etching step, and etching the isolation material layer to form unetched one of the plurality of isolation openings and the at least one light-transmitting opening.

That is, when the isolation material layer is etched to form an isolation structure, the isolation opening and the light-transmitting opening 1402 are formed respectively in two different etching processes. During the formation of the light-transmitting opening 1402 through etching, the isolation opening is protected by the other film layers; in one embodiment, during the formation of the isolation opening, the light-transmitting opening 1402 is protected by the other film layers.

In the manufacturing method for the display pane provided by the embodiment, by forming the isolation opening and the light-transmitting opening 1402 in different etching processes respectively, consistency of etching environment for the first display region AA1 and the second display region AA2 during the formation of the first isolation opening 1401 and the second isolation opening 1403 may be improved. Therefore, the isolation structure 140 in the first display region AA1 has a first undercut length SA21 at the first isolation opening 1401, and the isolation structure 140 in the second display region AA2 has a second undercut length SA22 at the second isolation opening 1403. A difference between the first undercut length SA21 and the second undercut length SA22 is less than 0.1 μm.

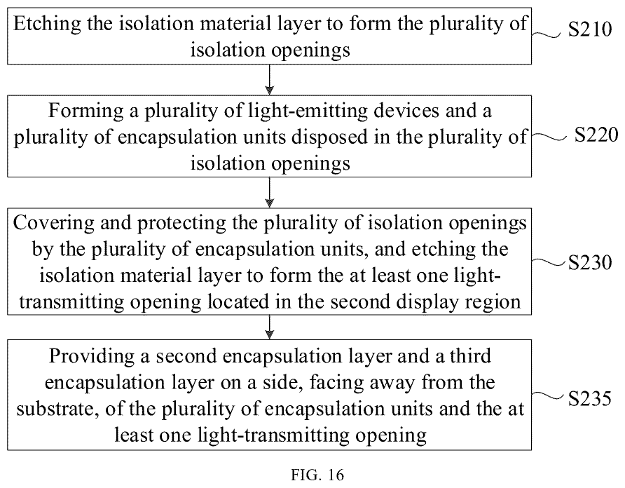

In some embodiments, referring to FIG. 16, step S130 may include the following sub-steps.
Step S210: etching the isolation material layer to form the plurality of isolation openings, where the plurality of isolation openings include the first isolation opening located in the first display region and the second isolation opening located in the second display region.

In the step S210, only the first isolation opening 1401 and the second isolation opening 1403 are formed through etching, and the light-transmitting opening 1402 will not be etched. In this case, in the step S210, a density of openings to be etched in the first display region AA1 is the same as that in the second display region AA2, and the first undercut length SA21 corresponding to the first isolation opening 1401 and the second undercut length SA22 corresponding to the second isolation opening 1403 are also substantially equal.

In one embodiment, after the etching process of the first isolation opening 1401 and the second isolation opening 1403 is completed, an etching process may also be performed on a pixel defining layer 130 to form a pixel opening.
Step S220: forming a plurality of light-emitting devices and a plurality of encapsulation units disposed in the plurality of isolation openings.

Therein, the plurality of encapsulation units are located on a side, facing away from the substrate, of the plurality of light-emitting devices.

In one embodiment, referring to FIG. 11, in the step S220, the light-emitting device and the encapsulation unit 170 may be formed in each isolation opening by performing full-surface evaporation for multiple times followed by etching. At least part of the encapsulation unit 170 extends, from the isolation opening and along a side wall, facing the isolation opening, of the isolation structure 140, to a side, facing away from the substrate 111, of the isolation structure. That is, the encapsulation unit 170 covers and protects the isolation structure 140 at the isolation opening.

During the process of forming the light-emitting device, since the first undercut length SA21 corresponding to each first isolation opening 1401 in the first display region AA1 and the second undercut length SA22 corresponding to each second isolation opening 1403 in the second display region AA2 are approximately the same, lap joint effect between the second electrode 160 and the isolation structure 140 in each light-emitting device is also approximately the same, improving light-emitting display uniformity of the light-emitting devices in the first display region AA1 and the second display region AA2.

In one embodiment, the light-emitting device formed in the step S220 may include a first-color light-emitting device and a second-color light-emitting device.

In one embodiment, the light-emitting device formed in the step S220 may further include a third-color light-emitting device. For example, the light-emitting device formed in the step S220 may include light-emitting devices with emission colors of red, green and blue, respectively.
Step S140 may include the following sub-steps.
Step S230: covering and protecting the plurality of isolation openings by the plurality of encapsulation units, and etching the isolation material layer to form the at least one light-transmitting opening located in the second display region.

In one embodiment, after the light-emitting device is formed in the step S220, the etching of the light-transmitting opening 1402 is then carried out to form the structure as shown in FIG. 4 or 5.

In the above process, in each first isolation opening 1401 and each second isolation opening 1403, the light-emitting device and the encapsulation unit 170 have been formed. The isolation structure 140 and the sidewalls, facing the isolation openings, of the isolation structure 140 may be protected by the encapsulation units 170 from etching damage. Consequently, the etching process of the light-transmitting opening 1402 may not affect the morphology of the isolation openings or affect the lap joint effect between the electrode of the light-emitting device and the isolation structure 140.

In some embodiments, after the step S230, the method may further include the following steps.
Step S235: providing a second encapsulation layer and a third encapsulation layer on a side, facing away from the substrate, of the plurality of encapsulation units and the at least one light-transmitting opening.

Therein, the second encapsulation layer 180 is located on a side, facing away from the substrate 111, of the plurality of encapsulation units 170 and the at least one light-transmitting opening 1402, and the third encapsulation layer 190 is located on a side, facing away from the substrate 111, of the second encapsulation layer 180.

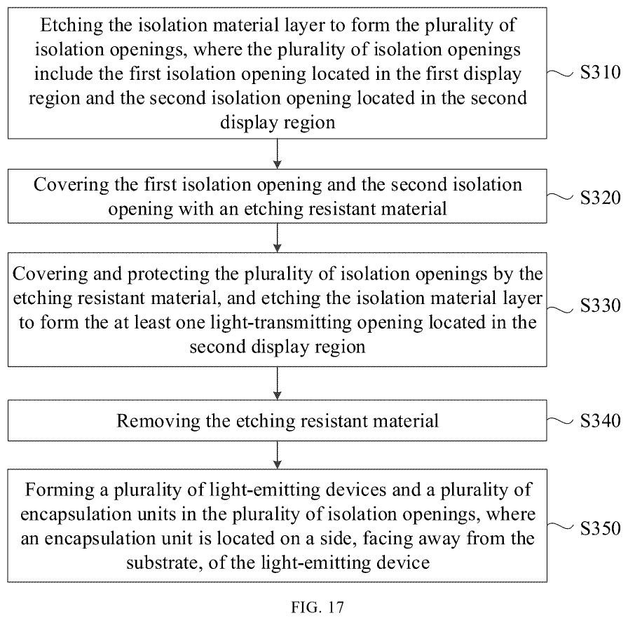

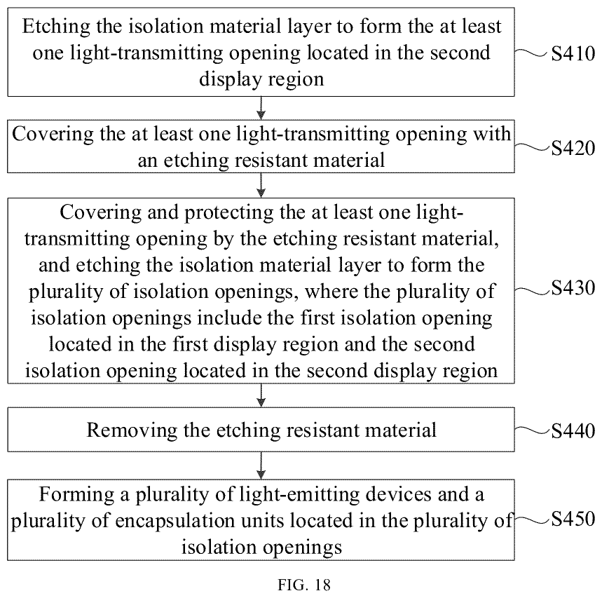

In other embodiments, as shown in FIG. 17, the step S130 may include the following sub-steps.
Step S310: etching the isolation material layer to form the plurality of isolation openings, where the plurality of isolation openings include the first isolation opening located in the first display region and the second isolation opening located in the second display region.

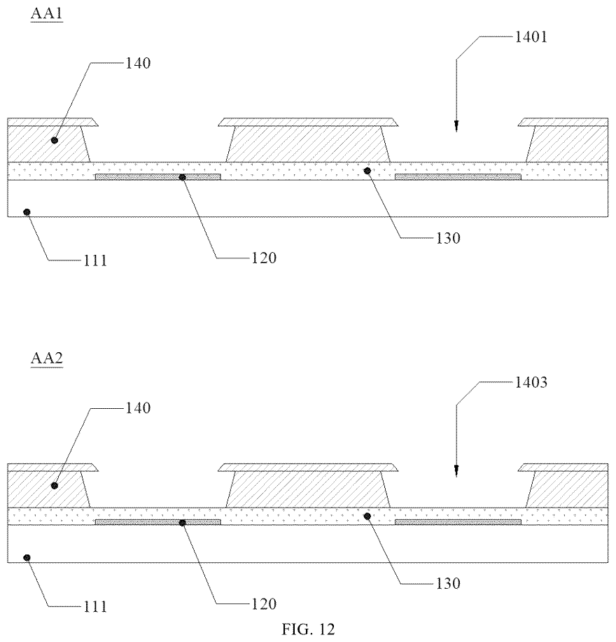

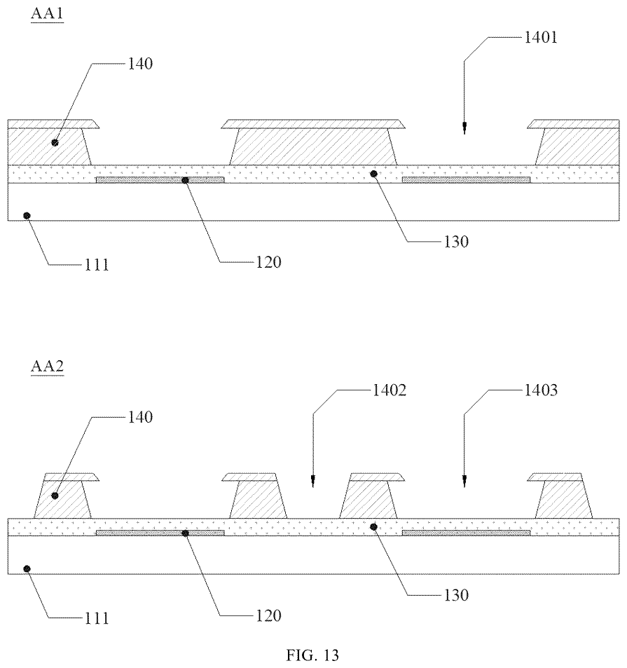

In one embodiment, referring to FIG. 12, in the step S310, the first isolation opening 1401 and the second isolation opening 1403 may be etched in the first display region AA1 and the second display region AA2 respectively.

In the step S310, only the first isolation opening 1401 and the second isolation opening 1403 are formed through etching, and the light-transmitting opening 1402 will not be etched. In this case, in the step S310, a density of openings to be etched in the first display region AA1 is the same as that in the second display region AA2, and the first undercut length SA21 corresponding to the first isolation opening 1401 and the second undercut length SA22 corresponding to the second isolation opening 1403 are also substantially equal.
Step S320: covering the first isolation opening and the second isolation opening with an etching resistant material.

In one embodiment, in the step S320, the etching resistant material such as photoresist may be applied to cover the first isolation opening 1401 and the second isolation opening 1403, and then the step S140 may be performed.

The step S140 may include the following sub-steps.
Step S330: covering and protecting the plurality of isolation openings by the etching resistant material, and etching the isolation material layer to form the at least one light-transmitting opening located in the second display region.
Step 340: removing the etching resistant material.

In one embodiment, in the step S330, since the first isolation opening 1401 and the second isolation opening 1403 are covered by the etching resistant material, the etching of the light-transmitting opening 1402 will not affect the morphology of the first isolation opening 1401 and the second isolation opening 1403. Therefore, after the etching process of the light-transmitting opening 1402 is completed, the first undercut length SA21 corresponding to the first isolation opening 1401 and the second undercut length SA22 corresponding to the second isolation opening 1403 are also substantially equal. Finally, the structure as shown in FIG. 13 is formed.

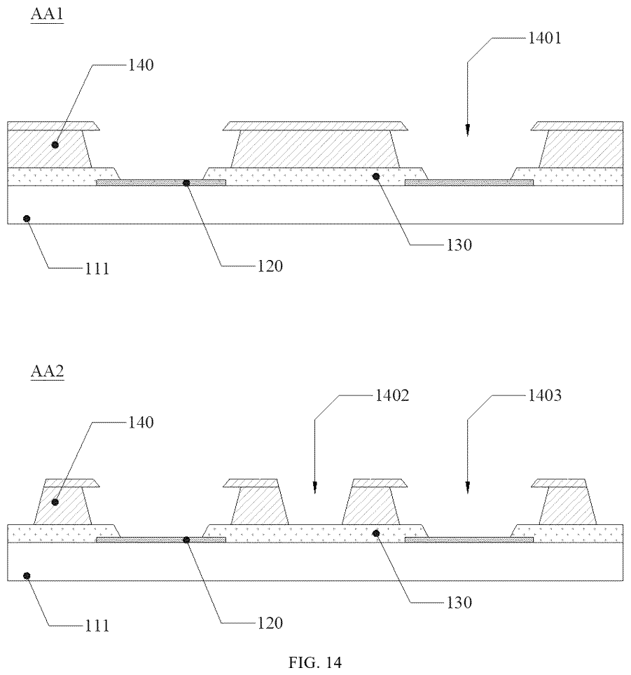

In one embodiment, after the step S330, an etching process may be further performed on the pixel defining layer 130 to form a pixel opening at a position corresponding to the isolation opening 1401, as shown in FIG. 14.

In one embodiment, after the step S340, the method may further include the following steps.
Step S350: forming a plurality of light-emitting devices and a plurality of encapsulation units in the plurality of isolation openings, where an encapsulation unit is located on a side, facing away from the substrate, of the light-emitting device. A structure as shown in FIG. 4 or 5 is then formed. Thus, as the isolation openings and the light-transmitting opening 1402 are formed by etching first, and then the light-emitting device is formed, it is possible to avoid damage to the light-emitting device during the etching of the light-transmitting opening 1402.

In other embodiments, as shown in FIG. 18, the step S130 may include the following sub-steps.
Step S410: etching the isolation material layer to form the at least one light-transmitting opening located in the second display region.

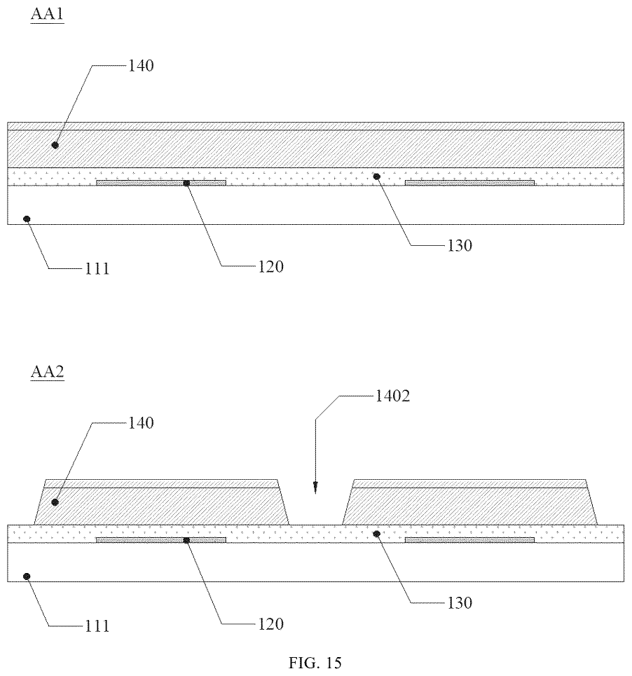

In one embodiment, referring to FIG. 15, in the step S410, dry etching or wet etching may be performed on the shielding portion 142 and the supporting portion 141 only one time to form the light-transmitting opening 1402.
Step S420: covering the at least one light-transmitting opening with an etching resistant material.

In one embodiment, in the step S420, the etching resistant material such as photoresist may be applied to cover the light-transmitting opening 1402, and then the step S140 is implemented.

The step S140 may include the following sub-steps.
Step S430: covering and protecting the at least one light-transmitting opening by the etching resistant material, and etching the isolation material layer to form the plurality of isolation openings, where the plurality of isolation openings include the first isolation opening located in the first display region and the second isolation opening located in the second display region.
Step S440: removing the etching resistant material.

During the above process, since the light-transmitting opening 1402 is covered by the etching resistant material, during the etching of the first isolation opening 1401 and the second isolation opening 1403, a position corresponding to the light-transmitting opening 1402 will not consume etching solution. Therefore, during the etching of the first isolation opening 1401 and the second isolation opening 1403, the etching environment for the first display region AA1 and the second display region AA2 are substantially the same. Therefore, in the first display region AA1 and the second display region AA2, the first undercut length SA21 corresponding to the first isolation opening 1401 and the second undercut length SA22 corresponding to the second isolation opening 1403 are also substantially equal, as shown in FIG. 12.

In one embodiment, after the step S430, the etching process may be further performed on the pixel defining layer 130 to form s pixel opening at a position corresponding to the isolation opening 1401, as shown in FIG. 14.

In one embodiment, after the step S440, the method may further include the following steps.
Step S450: forming a plurality of light-emitting devices and a plurality of encapsulation units located in the plurality of isolation openings. Then the structure as shown in FIG. 4 or 5 is formed. Thus, as the isolation openings and the light-transmitting opening 1402 are formed by etching first, and then the light-emitting device is provided, it is possible to avoid damage to the light-emitting device during the etching of the light-transmitting opening 1402.

In other embodiments, during the etching process performed on the isolation material layer to form the at least one light-transmitting opening 1402 in the second display region AA2, dry etching may be performed on the isolation material layer to form the isolation structure 140, located in the second display region AA2 and defining the at least one light-transmitting opening 1402.

Therein, the isolation structure 140 includes a supporting portion 141, and a shielding portion 142 located on a side, facing away from the substrate 111, of the supporting portion 141. A side, close to the light-transmitting opening 1402, of the shielding portion 142 located in the second display region AA2 is flush with a side, close to the light-transmitting opening 1402, of the supporting portion 141 located in the second display region AA2.

In other embodiments, during the etching process performed on the isolation material layer to form the at least one light-transmitting opening 1402 in the second display region AA2, wet etching may be performed on the isolation material layer to form the isolation structure 140, located in the second display region AA2 and defining the at least one light-transmitting opening 1402.

Therein, the isolation structure 140 includes a supporting portion 141, and a shielding portion 142 located on the side, facing away from the substrate 111, of the supporting portion 141. At the light-transmitting opening 1402, an orthogonal projection of a side, facing the shielding portion 142, of the supporting portion 141 disposed in the second display region AA2, on the substrate 111 is located within an orthogonal projection of the shielding portion 142 located in the second display region AA2, on the substrate 1112.

Furthermore, the display panel provided by the embodiments further includes a touch structure, optical films (such as microlenses, polarizing films), and cover plates, etc., disposed on a side, facing away from the substrate 111, of the third encapsulation layer 190, which will not be limited in the embodiments.

The present disclosure also provides an electronic device. The electronic device includes the display panel provided by the present disclosure, or a display panel manufactured by the manufacturing method for the display panel provided by the embodiments. The electronic device may include a mobile phone, a tablet computer, a smart wearable device, a television, a laptop, a monitor, and other devices with a display function.

In view of above, the embodiments of the present disclosure provide a display panel, a manufacturing method for the display panel, and an electronic device, by forming isolation openings and light-transmitting openings separately at different etching processes, and consistency of the etching environment for a first display region and a second display region during the formation of a first isolation opening and a second isolation opening may be improved, ensuring that undercut lengths corresponding to each first isolation opening and second isolation opening are the same, thereby improving uniformity of lap joint effect between electrodes of the light-emitting devices in the first display region and the second display region, and the isolation structure, and improving uniformity of display effect in the first display region and the second display region.

The above-described embodiments may be combined in any way. For the sake of conciseness, not every possible combination of the individual features has been described; nevertheless, any combination that does not give rise to contradiction shall be regarded as falling within the scope of the present disclosure.

The embodiments described above merely illustrate several implementations of the present disclosure. While the descriptions are relatively specific and detailed, but should not be construed as limiting the scope of the present disclosure. It should be noted that various modifications and improvements can be made, and all such modifications and improvements fall within the protection scope of the present disclosure. Therefore, the protection scope of the present disclosure shall be defined by the appended claims.

What is claimed is:

1. A display panel, provided with a first display region and a second display region, comprising:
a substrate; and
an isolation structure, disposed on a side of the substrate and in the first display region and the second display region, wherein the isolation structure comprises a supporting portion and a shielding portion arranged on a side, facing away from the substrate, of the supporting portion; the isolation structure is provided with a plurality of isolation openings and at least one light-transmitting opening, the plurality of isolation openings comprise a first isolation opening arranged in the first display region and a second isolation opening arranged in the second display region, the at least one light-transmitting opening is arranged in the second display region; at the first isolation opening and the second isolation opening, an orthogonal projection of a side, facing the shielding portion, of the supporting portion on the substrate is located within an orthogonal projection of a side, facing the supporting portion, of the shielding portion on the substrate;
wherein a distance between an orthogonal projection of the shielding portion, located in the first display region and at the first isolation opening, on the substrate and an orthogonal projection of the supporting portion, located in the first display region and at the first isolation opening, on the substrate is SA21; a distance between an orthogonal projection of the shielding portion, located in the second display region and at the second isolation opening, on the substrate and an orthogonal projection of the supporting portion, located in the second display region and at the second isolation opening, on the substrate is SA22; and a difference between SA21 and SA22 is less than 0.1 μm.

2. The display panel according to claim 1, further comprising a plurality of light-emitting devices, wherein the plurality of light-emitting devices comprise a plurality of first light-emitting devices and a plurality of second light-emitting devices, and the plurality of first light-emitting devices and the plurality of second light-emitting devices are configured to emit light of a first color;
the plurality of first light-emitting devices are located in the first display region, and a portion of a first light-emitting device is located within the first isolation opening; a distance between an orthogonal projection of the shielding portion, located in the first display region and at the first isolation opening corresponding to the first light-emitting device, on the substrate and an orthogonal projection of the supporting portion, located in the first display region and at the first isolation opening corresponding to the first light-emitting device, on the substrate is SA21; and
the plurality of second light-emitting devices are located in the second display region, and a portion of a second light-emitting device is located within the second isolation opening;
a distance between an orthogonal projection of the shielding portion, located in the second display region and at the second isolation opening corresponding to the second light-emitting device, on the substrate and an orthogonal projection of the supporting portion located in the second display region and at the second isolation opening corresponding to the second light-emitting device, on the substrate is SA22.

3. The display panel according to claim 1, wherein
a side, close to the at least one light-transmitting opening, of the shielding portion located in the second display region is flush with a side, close to the at least one light-transmitting opening, of the supporting portion located in the second display region; or
an orthogonal projection of a side, close to the shielding portion, of the supporting portion located in the second display region and close to the at least one light-transmitting opening, on the substrate is located within an orthogonal projection of the shielding portion, located in the second display region and close to the at least one light-transmitting opening, on the substrate.

4. The display panel according to claim 2, further comprising:
a plurality of encapsulation units, wherein at least part of an encapsulation unit is located within a corresponding isolation opening and extends from the corresponding isolation opening to a side, facing away from the substrate, of the isolation structure; the plurality of encapsulation units comprise a plurality of first encapsulation units located on a side, facing away from the substrate, of the plurality of second light-emitting devices; and
an orthogonal projection of a portion of the first encapsulation unit located on a side, facing away from the substrate, of the isolation structure, on the substrate is located within an orthogonal projection of the shielding portion on the substrate.

5. The display panel according to claim 4, further comprising a pixel defining layer located in the first display region and the second display region and disposed between the isolation structure and the substrate, wherein the pixel defining layer is provided with a plurality of pixel openings in communication with the plurality of isolation openings correspondingly; and
the at least one light-transmitting opening comprises a plurality of light-transmitting openings, at a same light-transmitting opening:
a side of the pixel defining layer, a side of the shielding portion, a side of the supporting portion, and a side of the first encapsulation unit are flush with each other; or
the side of the shielding portion is flush with the side of the first encapsulation unit, an orthogonal projection of a side, close to the shielding portion, of the supporting portion, on the substrate is located within the orthogonal projection of the shielding portion on the substrate; and a side, close to the supporting portion, of the pixel defining layer is not coplanar with a side, facing the light-transmitting opening, of the supporting portion.

6. The display panel according to claim 1, wherein the at least one light-transmitting opening comprises a plurality of light-transmitting openings, a light-transmitting opening is arranged between adjacent isolation openings; and a density of the plurality of isolation openings located in the first display region is the same as a density of the plurality of isolation openings located in the second display region.

7. The display panel according to claim 1, wherein the isolation structure further comprises: a transition portion, disposed between the supporting portion and the substrate, wherein an orthogonal projection of an end, close to an isolation opening, of the transition portion on the substrate is located within the orthogonal projection of the shielding portion on the substrate; and a material of the isolation structure meets at least one of the following requirements: a material of the transition portion comprises at least one of Molybdenum (Mo) and Titanium (Ti), a material of the supporting portion comprises Aluminium (Al), and a material of the shielding portion comprises Ti;
the display panel further comprises a plurality of light-emitting devices at least partially located within the plurality of isolation opening correspondingly, the light-emitting device comprises a first electrode, a light-emitting unit and a second electrode sequentially stacked in a direction away from the substrate; the isolation structure is conductive, and the second electrode extends to be electrically connected to the isolation structure; and an orthogonal projection of the at least one light-transmitting opening on the substrate and an orthogonal projection of the first electrode on the substrate do not completely coincide;
the display panel further comprises a pixel defining layer disposed between the isolation structure and the substrate, the pixel defining layer is provided with a plurality of pixel openings, and an orthogonal projection of a pixel opening on the substrate is located within an orthogonal projection of an isolation opening on the substrate;
the display panel further comprises a plurality of encapsulation units, an encapsulation unit is located on a side, facing away from the substrate, of the second electrode, at least part of the encapsulation unit is located within the isolation opening and extends from the isolation opening to a side, facing away from the substrate, of the isolation structure; and
the display panel further comprises a second encapsulation layer and a third encapsulation layer located on a side, facing away from the substrate, of the plurality of encapsulation units, wherein the second encapsulation layer is located on the side, facing away from the substrate, of the plurality of encapsulation units, and the first isolation opening and the second isolation opening are filled with the second encapsulation layer; a material of the encapsulation unit and the third encapsulation layer comprises an inorganic material, a material of the second encapsulation layer comprises an organic material; and the at least one light-transmitting opening is filled with the second encapsulation layer.

8. A display panel, provided with a first display region and a second display region, comprising [symbol]
a substrate;
an isolation structure disposed on a side of the substrate, wherein the isolation structure comprises a supporting portion and a shielding portion sequentially stacked in a direction away from the substrate, and an orthogonal projection of a side, facing the shielding portion, of the supporting portion, on the substrate is located within an orthogonal projection of the shielding portion on the substrate; the isolation structure is provided with a plurality of isolation openings and at least one light-transmitting opening, the plurality of isolation openings comprise a plurality of first isolation openings and a plurality of second isolation openings, the plurality of first isolation openings are arranged in the first display region, and the plurality of second isolation openings and the at least one light-transmitting opening are arranged in the second display region; and
a plurality of light-emitting devices, wherein the plurality of light-emitting devices comprise a plurality of first light-emitting devices and a plurality of second light-emitting devices emitting light of a first color, the plurality of first light-emitting devices are disposed in the first display region, the plurality of second light-emitting devices are disposed in the second display region, a portion of a first light-emitting device is located within a first isolation opening correspondingly, a portion of a second light-emitting device is located within a second isolation opening correspondingly;
wherein an orthogonal projection of a side, facing the substrate, of the supporting portion, on the substrate is a first orthogonal projection, an orthogonal projection of the shielding portion on the substrate is a second orthogonal projection; along a first direction, a distance between an edge of the first orthogonal projection and an edge of the second orthogonal projection at the first isolation opening corresponding to the first light-emitting device is SA21; a distance between an edge of the first orthogonal projection and an edge of the second orthogonal projection at the second isolation opening corresponding to the second light-emitting device is SA22; and SA21 is greater than SA22.

9. The display panel according to claim 8, wherein the at least one light-transmitting opening comprises a plurality of light-transmitting openings, along the first direction, a distance between an edge of the first orthogonal projection and an edge of the second orthogonal projection at the light-transmitting opening is SA0, and SA0 is greater than SA21.

10. The display panel according to claim 9, wherein the plurality of light-emitting devices further comprise a plurality of third light-emitting devices and a plurality of fourth light-emitting devices emitting light of a second color, the second color light is different from the first color light;
the plurality of third light-emitting devices are disposed in the first display region, a portion of a third light-emitting device is located within a first isolation opening correspondingly, and a distance between an edge of the first orthogonal projection and an edge of the second orthogonal projection at the first isolation opening corresponding to the third light-emitting device is SA23; and
the plurality of fourth light-emitting devices are disposed in the second display region, a portion of a fourth light-emitting device is located within a third isolation opening correspondingly, and a distance between an edge of the first orthogonal projection and an edge of the second orthogonal projection at the second isolation opening corresponding to the fourth light-emitting device is SA24; and
SA23 is greater than SA24, SA21 is greater than SA23, SA22 is greater than SA24, a difference between SA0 and SA21 is less than a difference between SA0 and SA23, and a difference between SA0 and SA22 is less than a difference between SA0 and SA24.

11. The display panel according to claim 10, wherein the plurality of light-emitting devices further comprise a plurality of fifth light-emitting devices and a plurality of sixth light-emitting devices emitting light of a third color, the first color, the second color and the third color are different from each other;
the plurality of fifth light-emitting devices are disposed in the first display region, a portion of a fifth light-emitting device is located within a first isolation opening correspondingly, a distance between an edge of the first orthogonal projection and an edge of the second orthogonal projection at the first isolation opening corresponding to the fifth light-emitting device is SA25;
the plurality of sixth light-emitting devices are disposed in the second display region, a portion of a sixth light-emitting device is located within a second isolation opening correspondingly, a distance between an edge of the first orthogonal projection and an edge of the second orthogonal projection at the second isolation opening corresponding to the sixth light-emitting device is SA26; and
SA25 is greater than SA26, SA23 is greater than SA25, SA24 is greater than SA26, a difference between SA0 and SA23 is less than a difference between SA0 and SA25, and a difference between SA0 and SA24 is less than a difference between SA0 and SA26.

12. The display panel according to claim 11, wherein SA0>SA21>SA22>SA23>SA24>SA25>SA26.

13. The display panel according to claim 9, wherein
a difference between SA21 and SA22 is less than or equal to 0.4 μm; or
a difference between SA0 and SA21 ranges from 0.1 μm to 0.4 μm; or
the difference between SA21 and SA22 is less than or equal to 0.4 μm and the difference between SA0 and SA21 ranges from 0.1 μm to 0.4 μm.

14. The display panel according to claim 8, further comprising [symbol]
a plurality of encapsulation units, wherein at least part of an encapsulation unit is located within a corresponding isolation opening and extends from the corresponding isolation opening to a side, facing away from the substrate, of the isolation structure, and the plurality of encapsulation units comprise a plurality of first encapsulation units located on a side, facing away from the substrate, of the plurality of second light-emitting devices; and
an orthogonal projection of a portion of the first encapsulation unit located on the side, facing away from the substrate, of the isolation structure, on the substrate is located within the second orthogonal projection.

15. The display panel according to claim 14, wherein the at least one light-transmitting opening comprises a plurality of light-transmitting openings, at a same light-transmitting opening:
a side of the shielding portion, a side of the supporting portion and a side of a first encapsulation unit are flush with each other; or
the side of the shielding portion is flush with the side of the first encapsulation unit, and an orthogonal projection of a side, facing the shielding portion, of the supporting portion, on the substrate is located within the orthogonal projection of the shielding portion on the substrate.

16. The display panel according to claim 14, wherein [symbol]
the display panel further comprises a pixel defining layer located in the first display region and the second display region, and disposed between the isolation structure and the substrate, wherein the pixel defining layer is provided with a plurality of pixel openings in communication with the plurality of isolation openings correspondingly;
the at least one light-transmitting opening comprises a plurality of light-transmitting openings, at the same light-transmitting opening:
a side of the pixel defining layer, a side of the shielding portion, a side of the supporting portion, and a side of the first encapsulation unit are flush with each other; or
a side, close to the supporting portion, of the pixel defining layer is not coplanar with a side, facing the light-transmitting opening, of the supporting portion.

17. The display panel according to claim 8, wherein the isolation structure further comprises [symbol]
a transition portion, disposed between the supporting portion and the substrate, wherein an orthogonal projection of an end, facing the supporting portion, of the transition portion, on the substrate is located within the orthogonal projection of the transition portion on the substrate; and
a material of the isolation structure meets at least one of the following requirements: a material of the transition portion comprises at least one of Molybdenum (Mo) and Titanium (Ti), a material of the supporting portion comprises Aluminium (Al), and a material of the shielding portion comprises Ti.

18. A manufacturing method for a display panel, wherein the display panel is provided with a first display region and a second display region, and the method comprises:
providing a substrate;
forming an isolation material layer on a side of the substrate, wherein the isolation material layer is located in the first display region and the second display region;
etching the isolation material layer in a first etching step to form a plurality of isolation openings, wherein the plurality of isolation openings comprise a first isolation opening arranged in the first display region and a second isolation opening arranged in the second display region; and covering and protecting the plurality of isolation openings by other film layers in a second etching step and etching the isolation material layer to form at least one light-transmitting opening; or
etching the isolation material layer in a first etching step to form at least one light-transmitting opening, wherein the at least one light-transmitting opening is arranged in the second display region; and covering and protecting the at least one light-transmitting opening by other film layers in a second etching step and etching the isolation material layer to form a plurality of isolation openings.

19. The method according to claim 18, wherein
the first etching step comprises:
etching the isolation material layer to form the plurality of isolation openings, wherein the plurality of isolation openings comprise the first isolation opening located in the first display region and the second isolation opening located in the second display region;
forming a plurality of light-emitting devices and a plurality of encapsulation units disposed in the plurality of isolation openings, wherein the plurality of encapsulation units are located on a side, facing away from the substrate, of the plurality of light-emitting devices; and
the second etching step comprises:
covering and protecting the plurality of isolation openings by the plurality of encapsulation units, and etching the isolation material layer to form the at least one light-transmitting opening located in the second display region.

20. The method according to claim 18, wherein
the first etching step comprises:
etching the isolation material layer to form the plurality of isolation openings, wherein the plurality of isolation openings comprise the first isolation opening located in the first display region and the second isolation opening located in the second display region; and
covering the first isolation opening and the second isolation opening with an etching resistant material; and
the second etching step comprises:
covering and protecting the plurality of isolation openings by the etching resistant material, and etching the isolation material layer to form the at least one light-transmitting opening located in the second display region; and
removing the etching resistant material;
wherein after the removing the etching resistant material, the method further comprises:
forming a plurality of light-emitting devices and a plurality of encapsulation units located in the plurality of isolation openings; wherein the plurality of encapsulation units are located on a side, facing away from the substrate, of the plurality of light-emitting devices.
